(19) United States
(12) Patent Application Publication
(10) Pub. No.: US 2015/0262667 A1
(43) Pub. Date: Sep. 17, 2015

(54) LOW POWER HIT BITLINE DRIVER FOR CONTENT-ADDRESSABLE MEMORY

(71) Applicant: LSI CORPORATION, San Jose, CA (US)

(72) Inventors: TRAVIS HEBIG, EAGAN, MN (US); CHRISTOHPER D. BROWNING, INVER GROVE HEIGHTS, MN (US); ERIC W. EKLUND, LAKEVILLE, MN (US); DANIEL M. NELSON, MINNEAPOLIS, MN (US); RICHARD J. STEPHANI, ST. PAUL, MN (US)

(73) Assignee: LSI CORPORATION, San Jose, CA (US)

(21) Appl. No.: 14/251,946

(22) Filed: Apr. 14, 2014

Related U.S. Application Data
(60) Provisional application No. 61/951,075, filed on Mar. 11, 2014.

(51) Int. Cl. G11C 15/04

(52) U.S. Cl. CPC G11C 15/04

(57) ABSTRACT

An apparatus includes a hit bitline driver circuit and an equalization control circuit. The hit bitline driver circuit may be configured to drive a pair of hit bitlines responsive to a search bit. The equalization control circuit may be configured to transfer charge from one hit bitline of the pair to the other hit bitline of the pair in response to the search bit changing state.

This application relates to U.S. Provisional Application No. 61/951,075, filed Mar. 11, 2014, which is hereby incorporated by reference in its entirety.

### FIELD OF THE INVENTION

The invention relates to memory devices generally and, more particularly, to a method and/or apparatus for implementing a low power hit bitline driver for content-addressable memory (CAM).

### BACKGROUND

Dynamic power reduction is becoming increasingly important in modern integrated circuit designs. Dynamic power is especially problematic in Ternary Content Addressable Memory (TCAM). TCAM is a specialized type of memory that performs a fast fully parallel search of the memory contents. TCAM is used extensively for pattern matching in networking chips. Dynamic power consumption and the noise introduced by the dynamic power consumption of TCAM is a major design constraint in networking chips. A major source of dynamic power consumption within TCAM is the hit bitline power. Hit bitlines span the entire height of the memory and are connected to every memory cell. Hit bitlines are traditionally constructed as dynamic signals that switch every cycle or static signals that are driven by CMOS logic and switch only when the data input is changed.

It would be desirable to have a method and/or apparatus for implementing a low power hit bitline driver for content-addressable memory (CAM).

### SUMMARY

The invention concerns an apparatus including a hit bitline driver circuit and an equalization control circuit. The hit bitline driver circuit may be configured to drive a pair of hit bitlines responsive to a search bit. The equalization control circuit may be configured to transfer charge from one hit bitline of the pair to the other hit bitline of the pair in response to the search bit changing state.

### BRIEF DESCRIPTION OF THE FIGURES

Embodiments of the invention will be apparent from the following detailed description and the appended claims and drawings in which:

FIG. 1 is a diagram illustrating an example of a content-addressable memory (CAM) in accordance with an embodiment of the invention;

FIG. 2 is a diagram illustrating an embodiment of a binary CAM cell row;

FIG. 3 is a diagram illustrating a hit bitline driver implemented in accordance with an embodiment of the invention;

FIGS. 4(A-E) are diagrams illustrating an example implementation of the hit bitline driver of FIG. 3;

FIG. 5 is a diagram illustrating various signals within the example implementation of the hit bitline driver of FIG. 3;

FIG. 6 is a diagram illustrating example power savings provided using an example implementation of the hit bitline driver of FIG. 3;

FIG. 7 is a flow diagram illustrating an example process in accordance with an embodiment of the invention.

### DETAILED DESCRIPTION OF THE EMBODIMENTS

Embodiments of the invention include providing a method and/or apparatus for implementing a low power hit bitline driver for content-addressable memory (CAM) that may (i) perform a comparison between a current state of each HBL and HBLB and a next state of each HBL and HBLB to determine if each HBL and HBLB will be switching, (ii) prior to a switching event, momentarily tri-stating the HBL and HBLB drivers, (iii) allow charge sharing between the HBL and HBLB to use the charge stored on the higher voltage line to raise the voltage level of the lower voltage line, (iv) enable the HBL and HBLB drivers to drive the HBL and HBLB voltages the rest of the way to VDD and VSS, (v) eliminate checking signal timing between input of search data input and clock signals, (vi) eliminate unnecessary charge sharing between hit bitlines associated with a data bit whose state has not changed, and/or (vii) be implemented as one or more integrated circuits.

In various embodiments, a method and/or apparatus is implemented, which provides a low power driver for hit bitlines in ternary content-addressable memories (TCAMs). Hit bitlines consume a significant portion of the total power of TCAMs and TCAMs consume a significant portion of the total power of networking chips. Thus, a method and/or apparatus that reduces power consumption by hit bitlines is extremely valuable to these applications.

Hit bitlines are typically constructed as true/complement wires. For example, when a hit bitline (HBL) is high, a corresponding hit bitline bar (HBLB) is low. In various embodiments, when one signal is high and the other is low and it is known that the signals need to switch to the opposite state, instead of driving the high signal line to ground with a traditional driver and wasting the charge stored on the high signal line, that charge is transferred to the low signal line to partially bring the low signal line high. Then, the low going line is driven the rest of the way low and the high going line is driven the rest of the way high. In various embodiments, power is reduced because a pair of hit bitlines is equalized only when an associated data input bit switches (changes state). The general concept can be extended to any highly loaded true/complement signal wires. In various embodiments, signal timing between a search data input signal (DIN) and clock signals does need to be checked, which (i) reduces designer workload and, therefore, time-to-market, and (ii) reduces circuit complexity and, therefore, silicon risk.

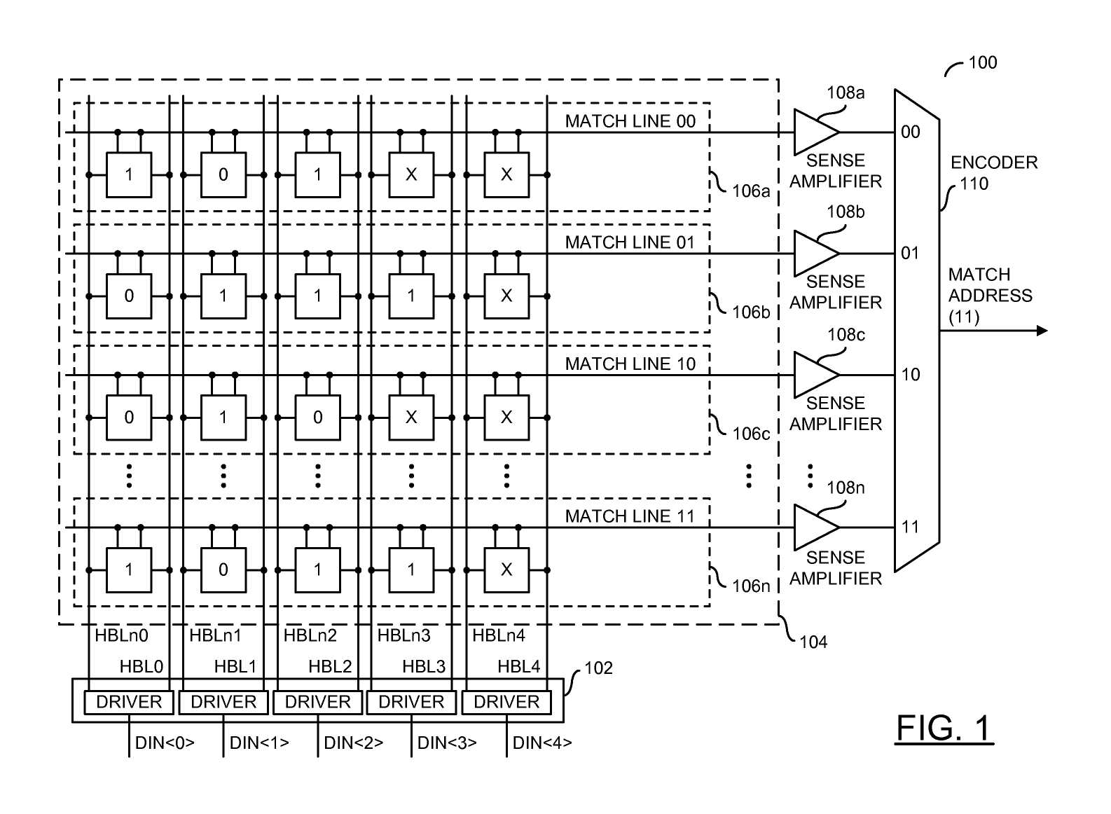

Referring to FIG. 1, a block diagram of a circuit 100 is shown illustrating an example of a content-addressable memory (CAM) in accordance with an embodiment of the invention. In various embodiments, the circuit 100 includes hit bitline (or search line) drivers 102, a n word by five bit CAM array 104 having memory cells arranged in rows 106a-106n, a number of sense amplifiers 108a-108n, and an encoder 110. In the example shown in FIG. 1, each of the number of memory cell rows 106a, 106b, 106c, . . . , 106n (corresponding to words) includes five memory cells (corresponding to the five bits) having individual storage and comparison circuitry. The search line drivers 102 provide five pairs of hit bitlines (e.g., HBLn0:HBL0, HBLn1:HBL1, HBLn2:HBL2, HBLn3:HBL3, HBLn4:HBL4). The pairs hit bitlines connect to corresponding columns having n memory cells, with each of the n memory cells located in one of the memory cell rows 106a, 106b, 106c, . . . , 106n. Each of the memory cell rows 106a, 106b, 106c, . . . , 106n employs a respective match line that is connected to each of the five CAM cells in the row. Each of the match lines is respectively connected to one of the sense amplifiers 108a, 108b, 108c, . . . , 108n, which in turn provide match line status to the encoder 110.

Each of the memory cell rows 106a, 106b, 106c, . . . , 106n contains a five bit search word that has been previously stored (employing bit lines and word lines not shown in FIG. 1). In the example shown in FIG. 1, at least one “X” designation is employed in each five bit search word to represent that either a “0” or a “1” state may be stored there. The match lines are pre-charged placing them in a “match” condition. Each of the search line drivers 102 broadcast a respective bit of a search word (e.g., DIN[0:4]) over the search line pairs HBLn0:HBL0, HBLn1:HBL1, HBLn2:HBL2, HBLn3:HBL3, HBLn4:HBL4 to each of the n CAM cells in each search line column. Memory cells containing bits corresponding to the respective search lines do not alter the match line pre-charge state even though a small match line leakage current condition exists. However, memory cells containing bits different from the respective search lines change the match line by discharging the pre-charged state of the match line with the exception that those having a stored X state do not affect match line conditions, in this example.

In various embodiments, generic and portable architectures are provided that employ binary, X-Y and ternary CAM (TCAM) cell arrays. These embodiments employ a low-power hit bitline equalization scheme provides charge sharing between pairs of hit bitlines to reduce dynamic and static power requirements for the binary, X-Y and ternary CAM arrays without significantly impacting performance or density. Hit bitline charge/discharge levels and rates may be configured over a range of search word lengths making applications especially attractive for embedded memories. Additionally, dynamic NOR Cell topology may be employed for the binary, X-Y and TCAM arrays that allows a significant reduction in design effort for embedded CAMs.

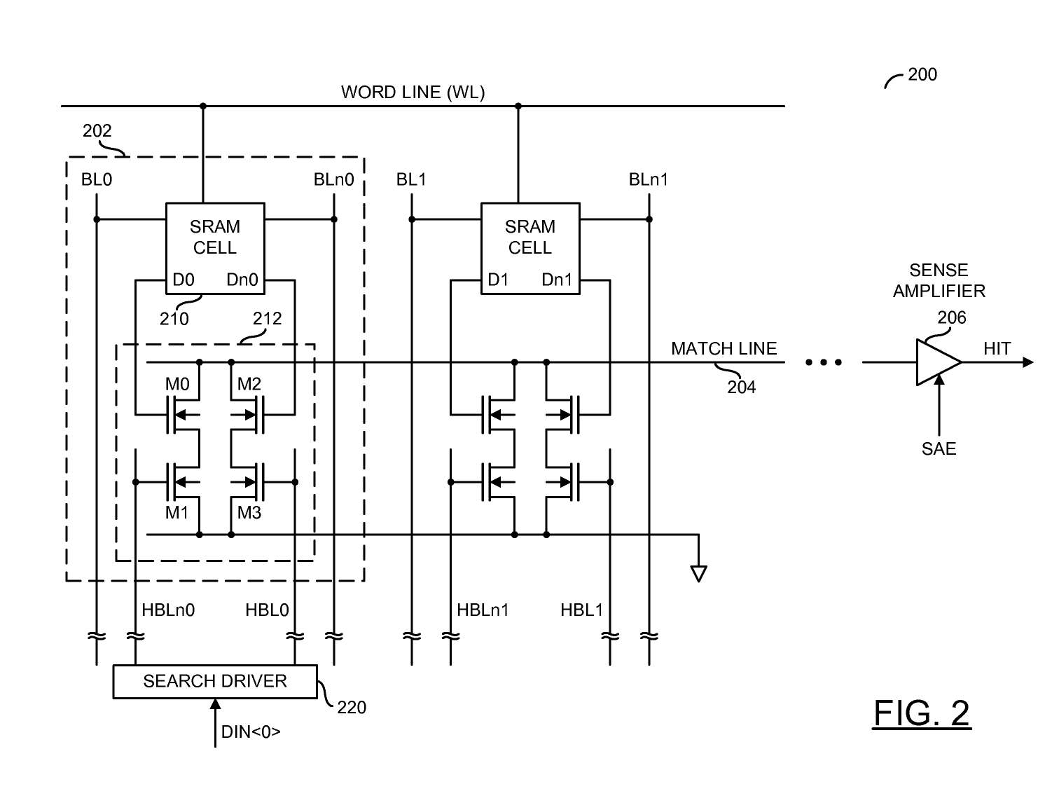

Referring to FIG. 2, a diagram is shown illustrating an example embodiment of a binary CAM cell row 200. The binary CAM cell row 200 may be employed in a binary CAM array and includes a plurality of binary CAM cells wherein the binary CAM cell 202 is typical. Each of the plurality of binary CAM cells in the binary CAM cell row 200 represents a bit in a search word for the binary CAM array. Typical CAM search word lengths may include 64, 128 or 256 bits, for example. However, other numbers of bits may be implemented to meet the design criteria of a particular implementation.

The binary CAM cell row 200 also includes a match line 204 and a sense amplifier 206. The binary CAM cell 202 includes a static random access memory (SRAM) cell 210 and a search line comparison circuit 212 employing comparison transistors M0, M1, M2 and M3. The search line comparison circuit 212 is connected to a pair of hit bitlines HBL0:HBLn0. The pair of hit bitlines HBL0:HBLn0 are driven by a search line driver 220, implemented in accordance with an embodiment of the invention.

Initially, a bit pattern (e.g., an address) to be subsequently searched is stored in the plurality of binary CAM cells of the binary CAM cell row 200 employing conventional memory bit lines and word lines. For example, the binary CAM cell 202 stores a search word bit employing a pair of bit lines (e.g., BL0 and BLn0) and a word line (e.g., WL), as shown in FIG. 2. Prior to initiating a search for a word, the match line 204 is pre-charged to a current sourcing voltage (e.g., VDD). After the match line 204 is pre-charged to VDD, the hit bitline pairs HBLn0:HBL0, HBLn1:HBL1, etc., are activated, initiating a simultaneous search of each of the plurality of binary CAM cells in the binary CAM cell row 200.

The search operation of the binary CAM cell 202 employs the comparison transistors M0, M1, M2 and M3 in the search line comparison circuit 212 and may be considered typical of each SRAM cell in the binary CAM cell row 200. As illustrated in FIG. 2, the comparison transistors M0 and M1 form a first stacked transistor pair M0:M1, and the comparison transistors M2 and M3 form a second stacked transistor pair M2:M3. Activation of both transistors in a stacked transistor pair causes the match line 204 to discharge. This condition may occur only when a mismatch condition exists.

Each pair of gate inputs for the first and the second stacked transistor pairs M0:M1, M2:M3 are cross-coupled in a logic sense. That is, an output D0 (true state) of the SRAM cell 210 is coupled with the hit bitline HBLn0 (complement state), and an output Dn0 (complement state) of the SRAM cell 210 is coupled with the hit bitline HBL0 (true state). In various embodiments, a column control (or mask) signal may be used to enable comparison of the contents of the SRAM cell 210 with the search bit DIN<0>. When the column control signal is not enabled, any state of the signal DIN<0> and the output D0 of the SRAM cell 210 provides a sense amplifier output that is a HIT. When the column control signal is enabled, the sense amplifier output is a HIT only when the states of the signal DIN<0> and output D0 are the same. When the states of HBL and D0 are not the same, the SRAM cell 210 provides a sense amplifier output that is not a HIT (e.g., a MISS or MISMATCH).

In the case of a complete word match where all hit bitline pairs (HBLn0:HBL0, HBLn1:HBL1, etc.) are complementary to their respective SRAM cell state pairs (D0:Dn0, D1:Dn1, etc.), the match line 204 discharges only by a few millivolts due to leakage current. For this case, the sense amplifier 206 outputs a signal value of TRUE corresponding to a HIT. During a typical mismatch condition, multiple combinations of hit bitline pairs (HBLn0:HBL0, HBLn1:HBL1, etc.) are the same as SRAM cell state pairs (D0:Dn0, D1:Dn1, etc.) thereby causing the match line 204 to discharge. This discharge occurs through a discharge path of the search line comparison circuits (such as the search line comparison circuit 212). A discharge condition will be evaluated by the sense amplifier 206, which outputs a signal value of FALSE corresponding to a MISMATCH.

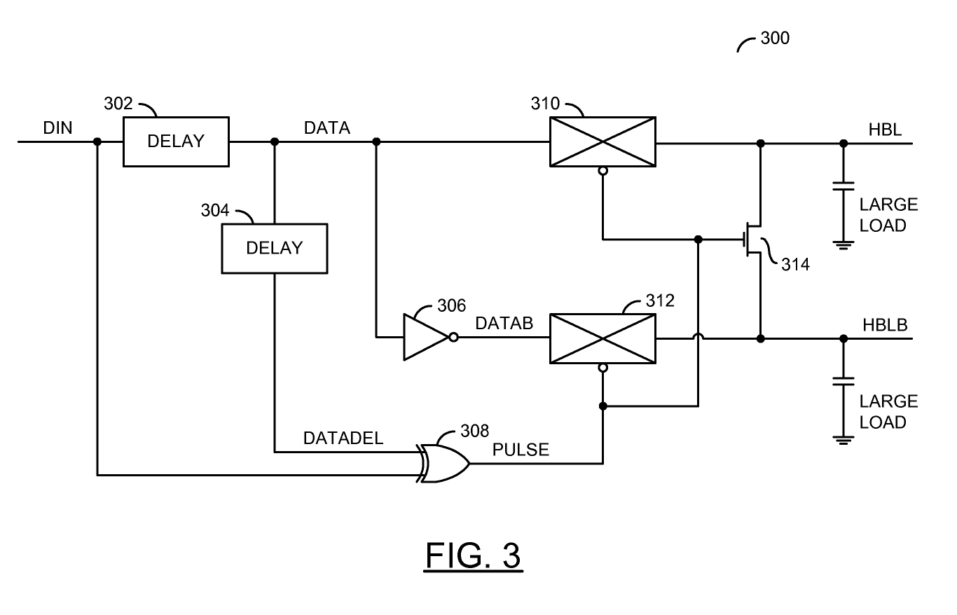

Referring to FIG. 3, a diagram of a circuit 300 is shown illustrating an example hit bitline driver in accordance with an example embodiment of the invention. In various embodiments, the circuit 300 may comprise a block (or circuit) 302, a block (or circuit) 304, a block (or circuit) 306, a block (or circuit) 308, a block (or circuit) 310, a block (or circuit) 312, and a block (or circuit) 314. The blocks 302 and 304 may be implemented as delay circuits. The block 306 may be implemented as an inverter. The blocks 310 and 312 may be implemented as transmission gates. The block 314 may implement a current transfer (or shorting) circuit. In one example, the block 314 may be implemented as a metal oxide semiconductor (MOS) field effect transistor (FET).

In various embodiments, the circuit 302 has an input that receives a signal (e.g., DIN) and an output that presents a signal (e.g., DATA). The signal DIN may be a search bit. The signal DATA is a delayed version of the signal DIN. The circuit 304 has an input theat receives the signal DATA and an output that presents a signal (e.g., DATADEL). The signal DATADEL is a delayed version of the signal DATA. The circuit 306 has an input that receives the signal DATA and an output that presents a complement of the signal DATA (e.g., DATAB). The circuit 308 has a first input that receives the signal DIN, a second input that receives the signal DATADEL and an output that presents a signal (e.g., PULSE). The circuit 308 is configured to generate the signal PULSE as a logical combination of the signals DIN and DATASEL. In various embodiments, the circuit 308 is configured to generate the signal PULSE as a logical exclusive-OR of the signals DIN and DATASEL.

The circuit 310 has an input that receives the signal DATA, a control terminal that receives the signal PULSE, and an output that is connected to the hit bitline HBL. The circuit 312 has an input that receives the signal DATAB, a control terminal that receives the signal PULSE, and an output that is connected to the hit bitline HBLB. The circuit 314 has a first terminal connected to the hit bitline HBL, a second terminal connected to the hit bitline HBLB, and a control terminal that receives the signal PULSE.

In an example operation, when the input signal DIN switches state (e.g., 0 to 1 or 1 to 0), the signal PULSE goes high immediately because current version of the signal DIN is now different from the delayed version DATADEL. When the signal PULSE goes high, the transmission gates 310 and 312 become opaque, the circuit 314 begins conducting, and charge begins to move from the higher charged to the lower charged of the hit bitlines HBL and HBLB. After a delay equal to the sum of the two delays provided by the circuit 302 and 304, the signal PULSE goes low. The signal PULSE going low turns off the circuit 314 and causes the transmission gates 310 and 312 to become transparent, allowing the hit bitlines HBL and HBLB to be driven the rest of the way to VSS and VDD. Power savings is realized through the charge sharing event. Instead of sinking the charge of the higher voltage node to ground, half of this charge is transferred to the lower voltage node before the signals are driven to the desired states.

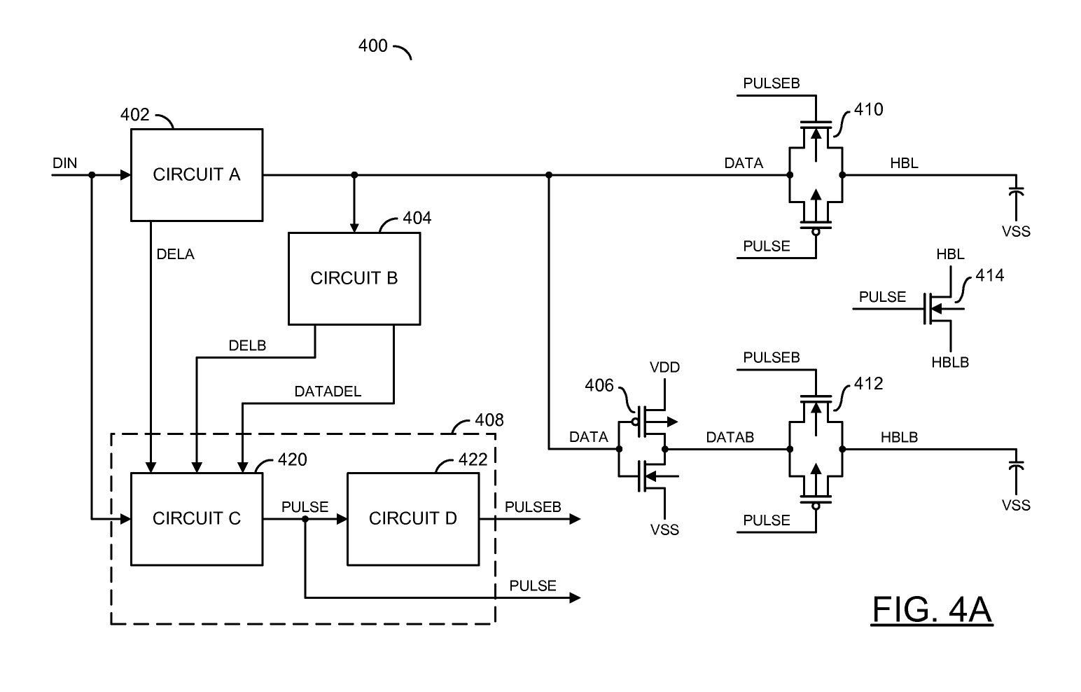

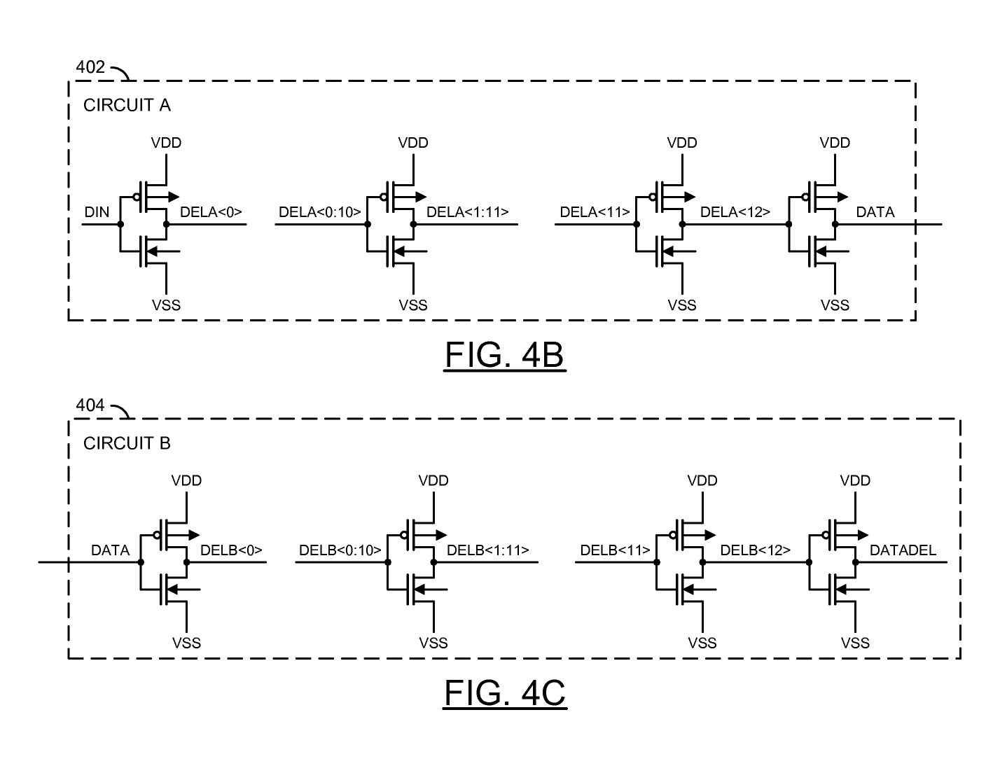

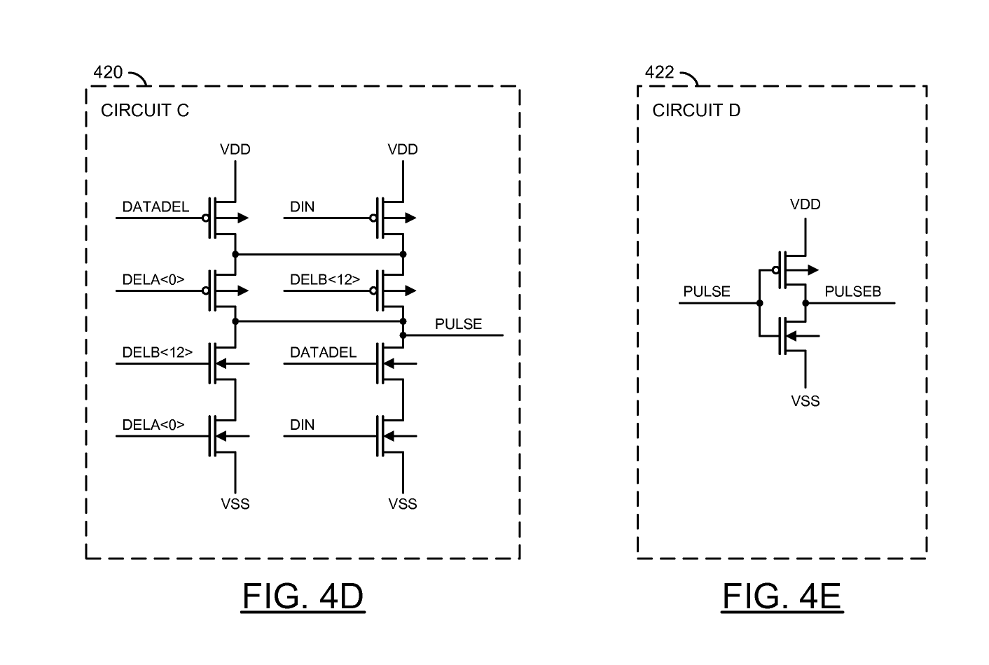

Referring to FIGS. 4(A-E), diagrams are shown illustrating an example implementation of the hit bitline driver of FIG. 3. FIG. 4A shows a circuit 400 that may be used to implement the circuit 300 of FIG. 3. In various embodiments, the circuit 400 may comprise a block (or circuit) 402, a block (or circuit) 404, a CMOS (complimentary metal oxide semiconductor) inverter 406, a block (or circuit) 408, a transmission gate 410, a transmission gate 412, and a transistor 414. The blocks 402 and 404 may implement delay circuits. The block 408 may implement an equalization control circuit. Each of the transmission gates 410 and 412 is implemented by a PMOSFET and an NMOSFET connected in parallel.

The circuit 402 receives the signal DIN and generates the signal DATA and a signal DELA. The signals DELA and DATA comprise a first delayed version and a second delayed version, respectively, of the signal DIN. The circuit 404 receives the signal DATA and generates the signal DATADEL and a signal DELB. The signals DELB and DATADEL comprise a third delayed version and a fourth delayed version, respectively, of the signal DIN. The inverter 406 generates a complement (e.g., DATAB) of the signal DATA. The circuit 408 receives the signals DIN, DELA, DELB, and DATADEL. The circuit 408 generates the signal PULSE and a signal PULSEB in response to the signals DIN, DELA, DELB, and DATADEL. The signal DATA is used to drive the hit bitline HBL via the transmission gate 310. The signal DATAB is used to drive the hit bitline HBLB via the transmission gate 312. The transmission gates 310 and 312 are control using the signals PULSE and PULSEB. The transistor 414 has a first drain/source connected the hit bitline HBL, a second drain/source connected the hit bitline HBLB, and a gate terminal receiving the signal PULSE.

In various embodiments, the circuit 408 comprises a block (or circuit) 420 and a block (or circuit) 422. The circuit 420 may be configured to generate the signal PULSE in response to the signal DIN, DELA, DELB, and DATADEL. The circuit 422 may be configured to generate the signal PULSEB in response to the signal PULSE.

Referring to FIG. 4B, a schematic diagram is shown illustrating an example implementation of the block 402 of FIG. 4A. In various embodiments, the circuit 402 may be implemented as a series (or chain) of CMOS inverters. The signal DIN is present to an input of a first CMOS inverter and the signal DATA is presented at an output of a last CMOS inverter in the chain. The signal DELA may be taken from an intermediate node in the chain.

Referring to FIG. 4C, a schematic diagram is shown illustrating an example implementation of the block 404 of FIG. 4A. In various embodiments, the circuit 404 may be implemented similarly to the circuit 402, as a series (or chain) of CMOS inverters. The signal DATA is present to an input of a first CMOS inverter and the signal DATADEL is presented at an output of a last CMOS inverter in the chain. The signal DELB may be taken from an intermediate node in the chain.

Referring to FIG. 4D, a schematic diagram is shown illustrating an example implementation of the block 420 of FIG. 4A. In various embodiments, the circuit 420 may comprise four PMOS field effect transistors (PFETs) and four NMOS field effect transistors (NFETs), arranged in two transistor stacks. A first transistor stack is formed by series connecting two PFETs and two NFETs. A second transistor stack is formed by series connecting the remaining two PFETs and two NFETs. Source-drain connections between the two PFETs in each stack are connected together. Source-drain connections between the a PFET and an NFET in each stack are connected together and to the output of the circuit 420. The signal DIN is presented to a gate of a first PFET in the second stack and a second NFET in the second stack. The signal DATADEL is presented to a gate of a first PFET in the first stack and a first NFET in the second stack. A signal (DELA<0>) is presented to a gate of a second PFET and a gate of a second NFET in the first stack. A signal (DELB<12>) is presented to a gate of a first NFET in the first stack and a gate of a second PFET in the second stack. The two transistor stacks are connected between VDD and VSS.

Referring to FIG. 4E, a schematic diagram is shown illustrating an example implementation of the circuit 422 as a CMOS inverter.

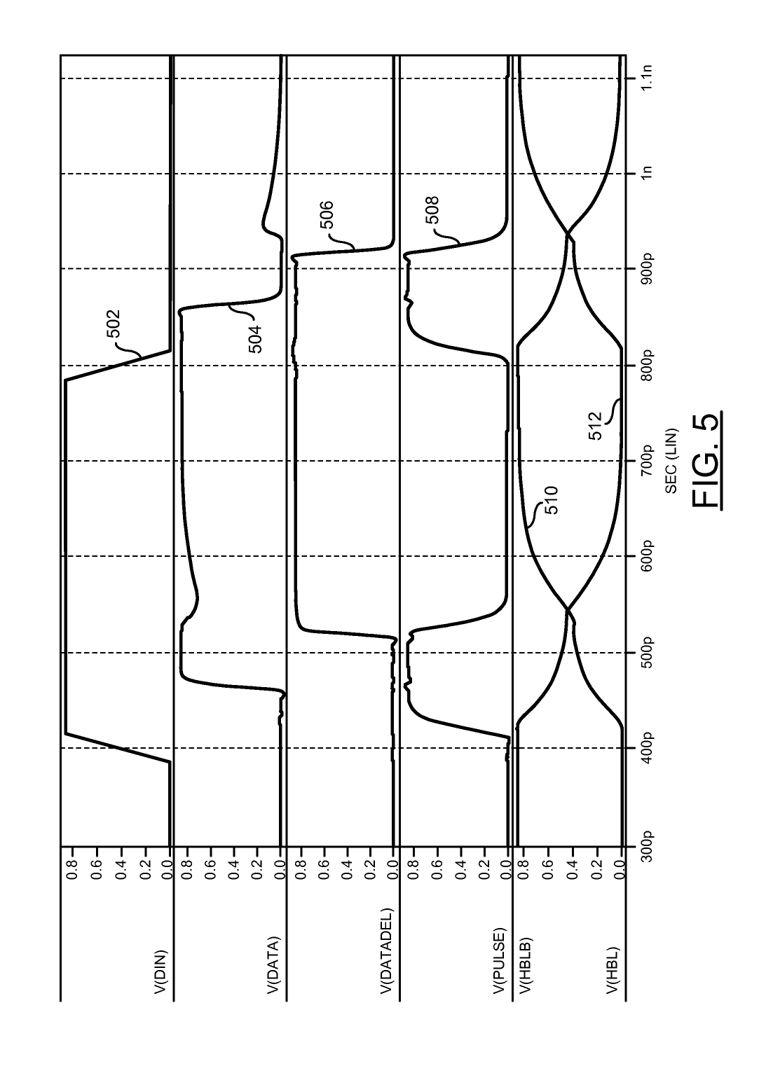

Referring to FIG. 5, a diagram is shown illustrating various signal waveforms produced by the circuit 300 of FIG. 4. A waveform 402 illustrates a signal V(DIN) representing a voltage level of a bit of the signal DIN changing state. A waveform 404 illustrates signal V(DATA) representing a voltage level of a first delayed version of the signal DIN. A waveform 406 illustrates a signal V(DATADEL) representing a voltage level of a second (further) delayed version of the signal DIN. A waveform 408 illustrates a signal V(PULSE) representing a voltage level of pulses that may be generated using edges of the signals DIN and DATADEL. Waveforms 410 and 412 illustrate a voltage levels of the hit bitlines HBL and HBLB, respectively, produced by the circuit 300 in response to the signal DIN changing state.

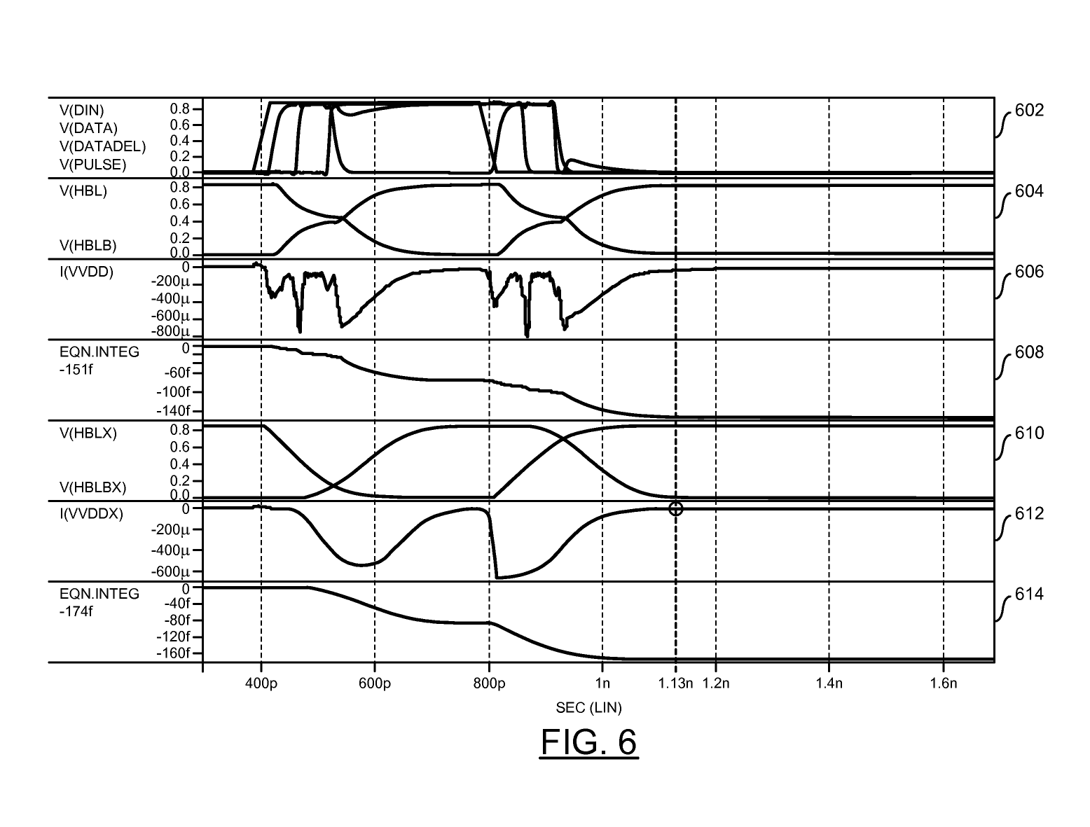

Referring to FIG. 6, a diagram is shown illustrating an example of dynamic power savings achieved using a search line driver in accordance with an embodiment of the invention. A pane 502 illustrate the control signals DIN, DATA, DATA DEL, and PULSE from FIG. 5. A pane 504 shows the HBL and HBLB waveforms from FIG. 5. A pane 506 shows a waveform representing an example power supply current of a hit bitline driver implemented in accordance with an embodiment of the invention. A pane 508 shows a waveform illustrate power consumed by the bitline driver implemented in accordance with an embodiment of the invention. The waveform of pane 508 is generated by integrated the current waveform of pane 506. Panes 510, 512, and 514 illustrate waveforms of a conventional search line driver corresponding to the waveforms of panes 504, 506, and 508, respectively. In the examples shown, a dynamic powers savings of 13% is obtained by a low-power search line driver in accordance with an embodiment of the invention.

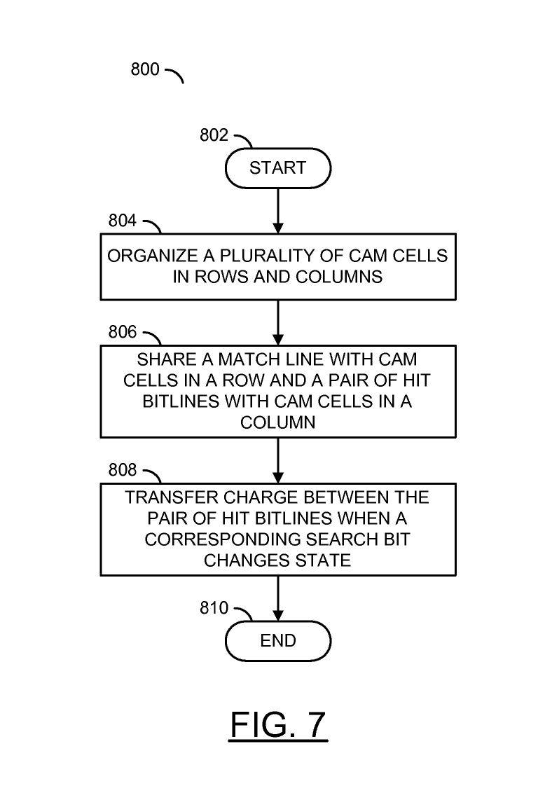

Referring to FIG. 7, a flow diagram of a process 800 is shown illustrating an embodiment of a method of operating an integrated circuit having a CAM array in accordance with an embodiment of the invention. The process (or method) 800 generally starts in a step 802 and then, in a step 804, a plurality of CAM cells are organized in rows and columns where each row corresponds to an address word and each column corresponds to a bit position. A match line is shared with CAM cells in each row, and a pair of hit bitlines are shared with CAM cells in each column, in a step 806. In a step 808, charge is transferred between a pair of hit bitlines when a corresponding search bit changes state. The process 800 ends in a step 810.

The terms “may” and “generally” when used herein in conjunction with “is(are)” and verbs are meant to communicate the intention that the description is exemplary and believed to be broad enough to encompass both the specific examples presented in the disclosure as well as alternative examples that could be derived based on the disclosure. The terms “may” and “generally” as used herein should not be construed to necessarily imply the desirability or possibility of omitting a corresponding element.

The various signals of the present invention are generally “on” (e.g., a digital HIGH, or 1) or “off” (e.g., a digital LOW, or 0). However, the particular polarities of the on (e.g., asserted) and off (e.g., de-asserted) states of the signals may be adjusted (e.g., reversed) to meet the design criteria of a particular implementation. Additionally, inverters may be added to change a particular polarity of the signals.

While the invention has been particularly shown and described with reference to embodiments thereof, it will be understood by those skilled in the art that various changes in form and details may be made without departing from the scope of the invention.

1. An apparatus comprising:
a hit bitline driver circuit configured to drive a pair of hit bitlines responsive to a search bit; and
an equalization control circuit configured to transfer charge from one hit bitline of the pair to the other hit bitline of the pair in response to the search bit changing state.

2. The apparatus according to claim 1, wherein said hit bitline driver circuit comprises:
a first delay circuit configured to generate a first delayed version of the search bit;
a second delay circuit configured to generate a second delayed version of the search bit;
a first transmission gate configured to drive a first hit bitline of the pair of hit bitlines in response to the first delayed version of the search bit and a control signal; and
a second transmission gate configured to drive a second hit bitline of the pair of hit bitlines in response to a complement of the first delayed version of the search bit and said control signal.

3. The apparatus according to claim 2, wherein said equalization control circuit comprises:
a control circuit configured to generate said control signal in response to said search bit and said second delayed version of said search bit; and
an charge transfer circuit configured to transfer charge between a first hit bitline of the pair of hit bitlines and a second hit bitline of the pair of hit bitlines in response to said control signal.

4. The apparatus according to claim 3, wherein said charge transfer circuit comprises a field effect transistor couple between said first hit bitline and said second hit bitline of the pair of hit bitlines.

5. The apparatus according to claim 1, wherein said control circuit implements an exclusive-OR logic function.

6. The apparatus according to claim 1, wherein said hit bitline driver circuit comprises:
a first delay circuit configured to generate a first delayed version of the search bit and a second delayed version of the search bit;
a second delay circuit configured to generate a third delayed version of the search bit and a fourth delayed version of the search bit;
a first transmission gate configured to drive a first hit bitline of the pair of hit bitlines in response to the second delayed version of the search bit and a control signal; and
a second transmission gate configured to drive a second hit bitline of the pair of hit bitlines in response to a complement of the second delayed version of the search bit and said control signal.

7. The apparatus according to claim 6, wherein said equalization control circuit comprises:
a control circuit configured to generate said control signal in response to said search bit, said first delayed version of said search bit, said third delayed version of said search bit, and said fourth delayed version of said search bit; and
an charge transfer circuit configured to transfer charge between said first hit bitline of the pair of hit bitlines and said second hit bitline of the pair of hit bitlines in response to said control signal.

8. A method of driving a pair of hit bitlines comprising the steps of:
driving a pair of hit bitlines responsive to a search bit; and
transferring charge from one hit bitline of the pair of hit bitlines to the other hit bitline of the pair of hit bitlines in response to the search bit changing state.

9. The method according to claim 8, wherein driving said pair of hit bitlines comprises:
generating a first delayed version of the search bit;
generating a second delayed version of the search bit;
driving a first hit bitline of the pair of hit bitlines in response to the first delayed version of the search bit and a control signal; and
driving a second hit bitline of the pair of hit bitlines in response to a complement of the first delayed version of the search bit and said control signal.

10. The method according to claim 9, wherein the step of transferring charge comprises:
generating said control signal in response to said search bit and said second delayed version of said search bit; and
transferring charge between said first hit bitline of the pair of hit bitlines and said second hit bitline of the pair of hit bitlines by using said control signal to turn on a field effect transistor.

11. The method according to claim 10, wherein generating said control signal comprises performing an exclusive-OR of said search bit and said second delayed version of said search bit.

12. The method according to claim 8, wherein driving said pair of hit bitlines comprises:
generating a first delayed version of the search bit and a second delayed version of the search bit;
driving a first hit bitline of the pair of hit bitlines in response to the second delayed version of the search bit and a control signal; and
driving a second hit bitline of the pair of hit bitlines in response to a complement of the second delayed version of the search bit and the control signal.

13. The method according to claim 12, wherein the step of transforming charge comprises:
generating a third delayed version of the search bit, and a fourth delayed version of the search bit;
generating said control signal in response to said search bit, said first delayed version of said search bit, said third delayed version of said search bit, and said fourth delayed version of said search bit; and
creating a current path between said first hit bitline of the pair of hit bitlines to said second hit bitline of the pair of hit bitlines in response to a first state of said control signal and removing said current path in response to a second state of said control signal.
